(19) United States
(12) Patent Application Publication
(10) Pub. No.: US 2025/0240039 A1
(43) Pub. Date: Jul. 24, 2025

(54) CONCURRENT MATCHING RECEIVER WITH IMPROVED NOISE FIGURE

(71) Applicant: QUALCOMM Incorporated, San Diego, CA (US)

(72) Inventors: Shinwoong PARK, Sunnyvale, CA (US); Bo QIAO, San Jose, CA (US); Sang Oh LEE, Cupertino, CA (US); Mazhareddin TAGHIVAND, San Jose, CA (US)

(21) Appl. No.: 18/420,367

(22) Filed: Jan. 23, 2024

(51) Int. Cl. H04B 1/04; H01F 38/14; H03F 3/24

(52) U.S. Cl. CPC H04B 1/04; H01F 38/14; H03F 3/24; H03F 2200/294; H04B 2001/0408

(57) ABSTRACT

Certain aspects of the present disclosure are directed towards techniques and apparatus for implementing concurrent matching for a transmitter and a receiver. An example transceiver may include: a transformer having a primary winding and a secondary winding; a first amplifier having a first output coupled to the primary winding; a second amplifier having an input coupled to a first terminal of the secondary winding, wherein a second terminal of the secondary winding is coupled to an antenna port of the transceiver; and a first inductive element coupled between the first terminal of the secondary winding and a reference potential node.

### TECHNICAL FIELD

Certain aspects of the present disclosure generally relate to electronic circuits and, more particularly, to techniques for signal reception and transmission implemented with concurrent matching.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include one or more transmitters and receivers.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include reduced transceiver noise.

Certain aspects of the present disclosure are directed towards a transceiver. The transceiver generally includes: a transformer having a primary winding and a secondary winding; a first amplifier having a first output coupled to the primary winding; a second amplifier having an input coupled to a first terminal of the secondary winding, wherein a second terminal of the secondary winding is coupled to an antenna port of the transceiver; and a first inductive element coupled between the first terminal of the secondary winding and a reference potential node.

Certain aspects of the present disclosure are directed towards a method for wireless communication. The method generally includes: electrically shorting, via a first amplifier, a primary winding of a transformer to a reference potential node during a receive mode, wherein a first terminal of a secondary winding of the transformer is coupled to an input of a second amplifier, and wherein a second terminal of the secondary winding is coupled to an antenna; and amplifying, via the second amplifier, a signal received from the antenna through the secondary winding of the transformer.

Certain aspects of the present disclosure are directed towards a wireless device. The wireless device generally includes: an antenna; a transformer having a primary winding and a secondary winding; a first amplifier having an output coupled to the primary winding; a second amplifier having an input coupled to a first terminal of the secondary winding, wherein a second terminal of the secondary winding is coupled to the antenna; and an inductive element coupled between the second terminal of the secondary winding and a reference potential node.

Certain aspects of the present disclosure are directed towards a transceiver. The transceiver generally includes: a transformer having a primary winding and a secondary winding; a first amplifier having a first output coupled to the primary winding; a second amplifier having an input coupled to a first terminal of the secondary winding, wherein a second terminal of the secondary winding is coupled to an antenna port of the transceiver, and wherein the first amplifier is configured to electrically short a first terminal and a second terminal of the primary winding to a reference potential node during a receive mode of the transceiver.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) and user equipment (UE), in which aspects of the present disclosure may be practiced.

FIG. 3 is a block diagram of an example radio frequency (RF) transceiver, in which aspects of the present disclosure may be practiced.

FIGS. 4A and 4B illustrate a transceiver, in accordance with certain aspects of the present disclosure.

FIGS. 5A and 5B illustrate the impact of a parasitic capacitance of a transformer on the operation of an amplifier, in accordance with certain aspects of the present disclosure.

FIG. 6 illustrates the transceiver in receive mode with an amplifier used to couple a primary winding to a reference potential node, in accordance with certain aspects of the present disclosure.

FIG. 7 illustrates a transceiver having a shunt inductive element and a direct-current (DC) blocking capacitive element, in accordance with certain aspects of the present disclosure.

FIG. 8 is a flow diagram illustrating example operations for wireless communication, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards techniques and apparatus for implementing concurrent matching for a transmitter and a receiver. In other words, a power amplifier (PA) of a transmitter may drive a primary winding of a transformer during transmit mode, where the secondary winding of the transformer is coupled to an antenna for signal transmission. During receive mode, the secondary winding of the transformer may be coupled to an inductive element for impedance matching for a low-noise amplifier (LNA) of the receiver. In some aspects, the primary winding may be coupled to a reference potential node (e.g., electrical ground) during receive mode so that the resonance associated with the transformer and PA output capacitance can be removed during the receive mode, which would otherwise degrade the LNA performance, as described in more detail herein.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

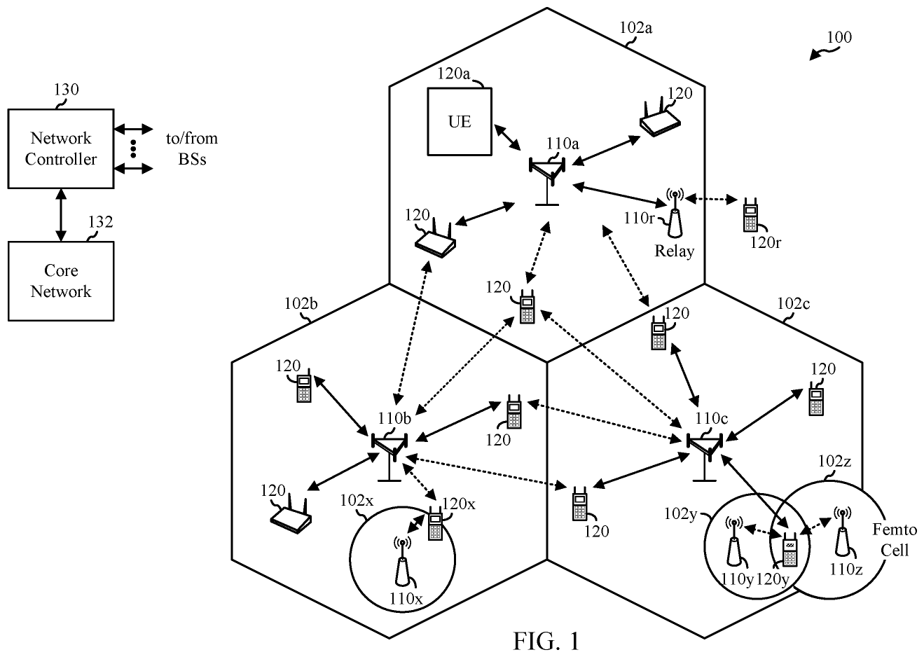

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to Nan, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nap of antennas to achieve transmit diversity for downlink transmissions and/or receive diversity for uplink transmissions. A set Nu of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nu UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include a transceiver implemented with concurrent matching, as described in more detail herein.

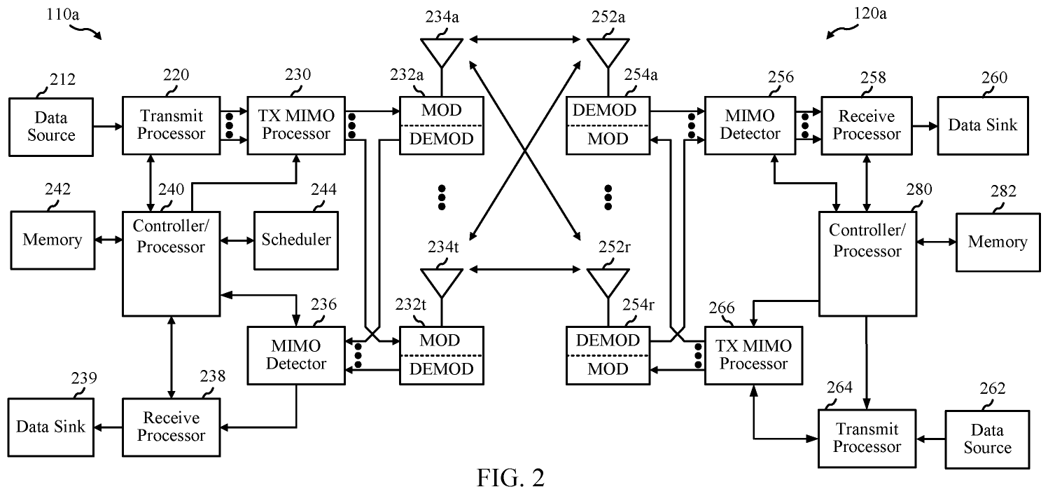

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

In certain aspects of the present disclosure, the transceivers 232 and/or the transceivers 254 may be implemented with concurrent matching, as described in more detail herein.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

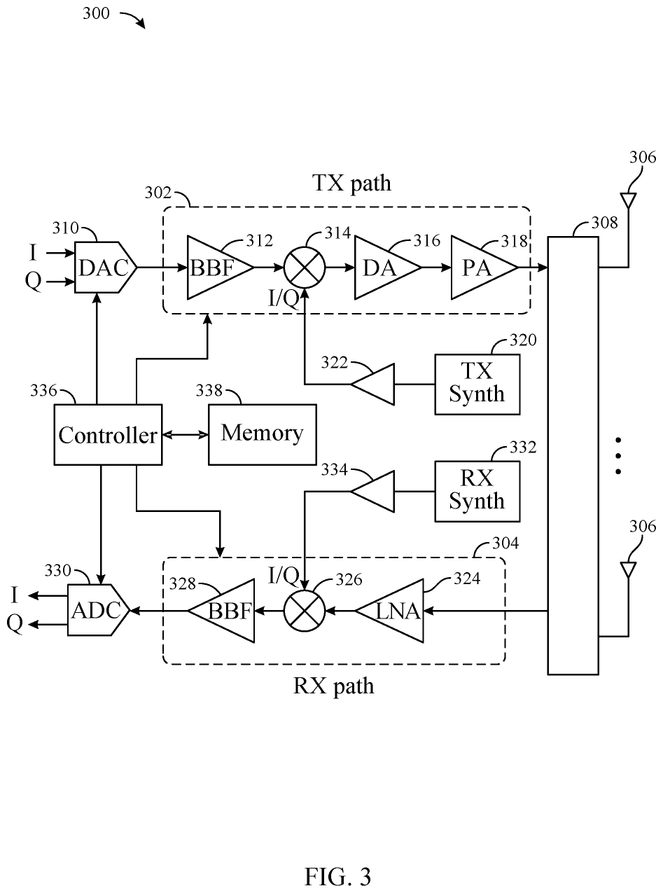

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing. In some aspects, concurrent matching may be implemented for the PA 318 and LNA 324, as described in more detail herein.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

While FIGS. 1-3 provide wireless communications as an example application in which certain aspects of the present disclosure may be implemented to facilitate understanding, certain aspects described herein may be used for any of various other suitable systems.

### Example Techniques for Concurrent Matching

In some time division multiple access (TDMA) radios, such as WiFi, Bluetooth, Zigbee, and long-term evolution (LTE), the radio frequency (RF) input/output pin may be shared between the PA (e.g., PA 318) and the LNA (e.g., LNA 324). This pin sharing may be desirable to reduce the pin count, thereby reducing area consumption, while avoiding usage of an external transmit-receive (TR) switch, which causes loss at the input (e.g., degrading sensitivity) and adds extra cost to the bill of materials (BOM) for a wireless device with one or more TDMA radios. Some implementations use a TR switch (e.g., a duplexer) that, in receive mode, is used to couple the antenna to the receiver and that, in transmit mode, is used to couple the antenna to the transmitter. Therefore, two pins may be used for coupling the receiver and transmitter of the transceiver chip to the TR switch and antenna. Some implementations use a circuit that facilitates using a single pin for coupling the receiver and the transmitter to the antenna, reducing the pin count for the transceiver chip.

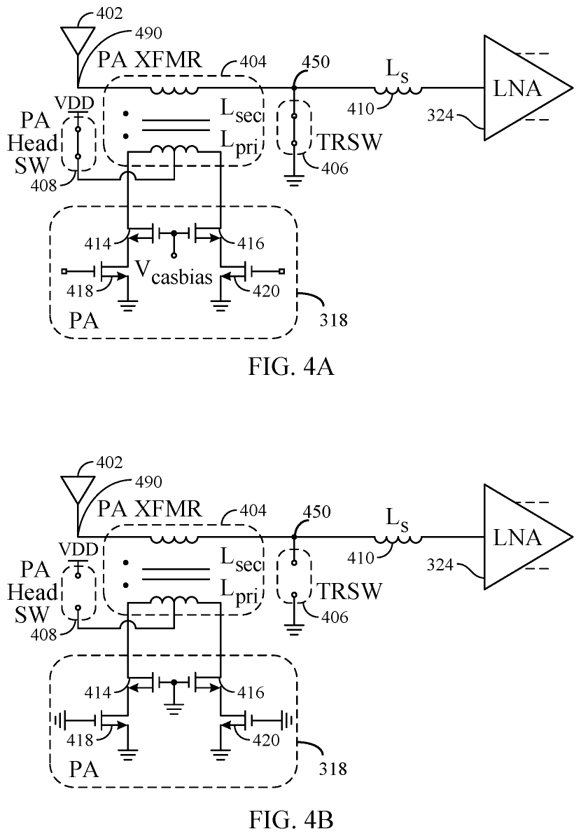

FIGS. 4A and 4B illustrate a transceiver 400, in accordance with certain aspects of the present disclosure. The transceiver 400 may represent a portion of a transceiver circuit, such as the RF transceiver circuit 300 of FIG. 3. As shown, the transceiver 400 includes a PA 318 having outputs coupled to respective terminals of a primary winding (Lₚᵣᵢ) of a transformer 404. The PA may include input transistors 418, 420 (e.g., transconductance transistors) receiving respective differential input voltages Vip and Vin (each of Vip and Vin may represent an input node of the transceiver). The sources of transistors 418, 420 (n-type field-effect transistors (NFETs)) are coupled to the reference potential node of the transceiver 400. The drains of transistors 418, 420 are coupled to sources of cascode transistors 414, 416 (e.g., NFETs), where drains of the transistors 414, 416 are coupled to the respective terminals of the primary winding of the transformer 404. As shown, the gates of the transistors 414, 416 may be biased using a bias voltage (V_{casbias}).

As shown, a secondary winding (L_{sec}) of the transformer 404 may be coupled to the antenna 402 via antenna port 490. The transceiver 400 uses concurrent matching for the LNA 324. For example, the secondary winding L_{sec} of the transformer 404 is also coupled between the antenna and the input of the LNA 324 through a series inductive element 410 (Lₛ). With concurrent matching, an external TR switch (e.g., duplexer) that would otherwise cause losses and increased costs may not be used. Moreover, without the TR switch, the number of pins (e.g., connection balls) for the transceiver chip may be reduced, as described herein.

To implement concurrent matching, the tap (e.g., center tap) of the primary winding Lₚᵣᵢ may be selectively coupled to a voltage rail VDD through a PA head switch (SW) 408, and a switch 406 (e.g., a transmit-receive switch (TRSW)) may selectively couple the reference potential node (e.g. electrical ground) to a node 450 between the secondary winding of transformer 404 and inductive element 410. During transmit mode, the transceiver 400 may be configured as shown in FIG. 4A. In transmit mode, the switches 406, 408 are closed, coupling the node 450 to the reference potential node and coupling the tap of the primary winding to VDD to power the PA. In this configuration, the secondary winding is electrically coupled between the antenna 402 and the reference potential node for wireless transmission via the antenna. During receive mode, the transceiver 400 may be configured as shown in FIG. 4B. In receive mode, the PA may be turned off and configured with high output impedance by coupling the gates of transistors 414, 416, 418, 420 to the reference potential node and opening switch 408 to decouple the tap of the primary winding from the voltage rail. Moreover, the switch 406 is opened so that the secondary winding of the transformer is effectively in series with the inductive element 410 for LNA input matching. Coupling the gates of transistors 414, 416, 418, 420 to the reference potential node results in a high effective capacitance at the primary winding of the transformer 404.

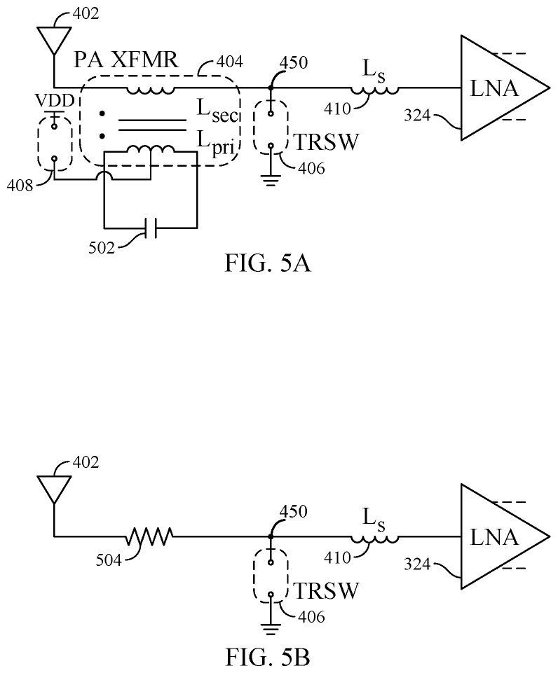

FIGS. 5A and 5B illustrate the impact of a parasitic capacitance of the transformer on the LNA operations. As shown in FIG. 5A, when in receive mode, a parasitic capacitance (CPA) 502 may exist between the terminals of the primary winding of the transformer 404. The parasitic capacitance makes it challenging to design an LNA input network. For example, if the transformer inductance and the parasitic capacitance CPA resonate around a frequency of interest (e.g., at a frequency within the receive band), the secondary winding of the transformer 404 effectively behaves as a resistance (e.g., represented by resistive element 504 in FIG. 5B), which degrades the LNA performance.

The PA output network design is intended to have resonance associated with the output capacitance of the PA and the transformer inductance for transmission. This resonance does not change (or changes little) from when the PA is on to when the PA is off. Therefore, the PA output capacitance should be reduced from when the PA is on to when the PA is off in receive mode so that the resonance associated with the transformer inductance and PA output capacitance is not within the receive band in the receive mode. However, reducing the PA output capacitance may be challenging without degrading the PA performance. For example, a capacitive element may be coupled to the output of the PA via a switch in transmit mode and decoupled from the output of the PA via the switch in receive mode. Thus, the resonance frequency may be shifted to higher frequencies in receive mode (e.g., shifted outside the receive band in receive mode). However, if the capacitive element is coupled to the output of the PA, the transformer inductance may have to be reduced to maintain the proper resonance frequency in transmit mode, resulting in degradation of the performance of the PA due to a reduced quality factor (Q). Certain aspects of the present disclosure are directed towards using a PA as a switch to couple the primary winding of the transformer 404 to the reference potential node (electric ground), reducing the secondary winding impedance and shifting the resonance frequency outside the receive band.

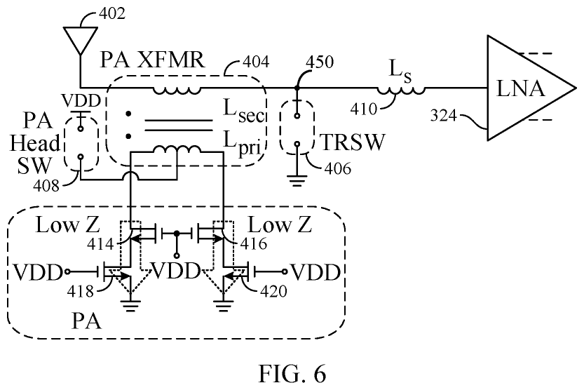

FIG. 6 illustrates the transceiver 400 in receive mode with the PA 318 being used to couple the primary winding to a reference potential node, in accordance with certain aspects of the present disclosure. As shown, in receive mode, the gates of transistors 414, 416, 418, 420 may be coupled to a voltage rail VDD, turning on transistors 414, 416, 418, 420 to effectively short the terminals of the primary winding to the reference potential node as shown. Thus, a low-impedance (low Z) path may be provided from the terminals of the primary winding to the reference potential node. As the primary winding terminals are shorted to the reference potential node through the large switches (transistors) of the PA 318, parasitic capacitance (CPA) 502 is removed and the secondary winding of transformer 404 becomes free (or close to free) of parallel resonance. With the switch 408 being open, substantial current leakage from the voltage rail VDD to the reference potential node through the PA may be prevented.

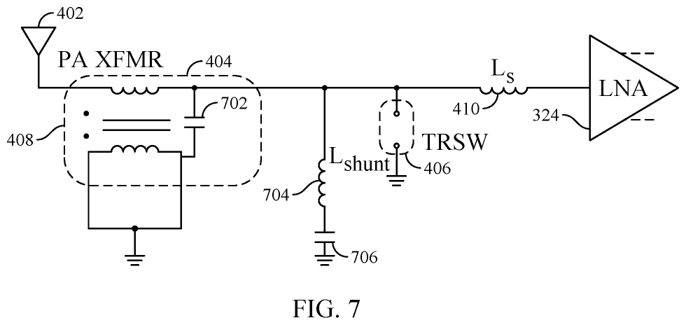

FIG. 7 illustrates a transceiver 700 having a shunt inductive element 704 (Lₛₕᵤₙₜ) and a direct-current (DC)-blocking capacitive element 706, in accordance with certain aspects of the present disclosure. As described above with respect to FIG. 6, the terminals of the primary winding of the transformer 404 may be coupled to the reference potential node (e.g., electric ground) through the PA 318 configured with low Z. As a result, the parasitic capacitance 702 between the primary and secondary windings of the transformer 404 adversely impacts the input matching and noise performance for the LNA 324. Thus, the inductive element 704 may be coupled between the node 450 and the reference potential node to counteract (e.g., cancel) the effects of the parasitic shunt capacitance 702 on the LNA input matching. As shown, the DC-blocking capacitive element 706 may be coupled in series with the inductive element 704 to block any DC signals from being shunted by inductive element 704.

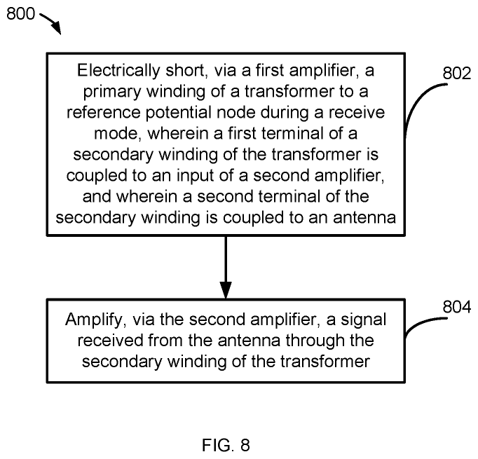

FIG. 8 is a flow diagram illustrating example operations 800 for wireless communication, in accordance with certain aspects of the present disclosure. The operations 800 may be performed, for example, by a transceiver, such as the transceiver 400 or transceiver 700.

At block 802, the transceiver may electrically short, via a first amplifier (e.g., PA 318), a primary winding of a transformer (e.g., transformer 404) to a reference potential node during a receive mode. A first terminal of a secondary winding of the transformer may be coupled to an input of a second amplifier (e.g., LNA 324). A second terminal of the secondary winding may be coupled to an antenna (e.g., antenna 402). At block 804, the transceiver may amplify, via the second amplifier, a signal received from the antenna through the secondary winding of the transformer (e.g., during the receive mode, while the primary winding of the transformer is shorted to the reference potential node).

In some aspects, a first inductive element (e.g., inductive element 704) is coupled between the first terminal of the secondary winding and the reference potential node. A capacitive element (e.g., capacitive element 706) may be coupled in series with the first inductive element between the first terminal of the secondary winding and the reference potential node.

In some aspects, the transceiver may couple (e.g., via switch 408) a voltage rail to a tap of the primary winding during a transmit mode. The transceiver may amplify, via the first amplifier (e.g., PA 318), a signal to be provided to the primary winding of the transformer for transmission during the transmit mode. In some aspects, the transceiver may couple (e.g., via switch 406) the first terminal of the secondary winding to the reference potential node during the transmit mode.

In some aspects, controlling the first amplifier to short the primary winding of the transformer to the reference potential node may include turning on a transistor (e.g., transistor 414 and transistor 418) of the first amplifier coupled between the primary winding and the reference potential node. In some aspects, the first amplifier may include an input transistor (e.g., transistor 418) including a gate coupled to an input node and a cascode transistor (e.g., transistor 414) coupled in cascode between the input transistor and the primary winding. Controlling the first amplifier to short the primary winding of the transformer to the reference potential node may include providing a supply voltage (e.g., VDD) to gates of the input transistor and the cascode transistor.

### Example Aspects

In addition to the various aspects described above, specific combinations of aspects are within the scope of the present disclosure, some of which are detailed below:

Aspect 1: A transceiver, comprising: a transformer having a primary winding and a secondary winding; a first amplifier having a first output coupled to the primary winding; a second amplifier having an input coupled to a first terminal of the secondary winding, wherein a second terminal of the secondary winding is coupled to an antenna port of the transceiver; and a first inductive element coupled between the first terminal of the secondary winding and a reference potential node.

Aspect 2: The transceiver of Aspect 1, further comprising a capacitive element coupled in series with the first inductive element between the first terminal of the secondary winding and the reference potential node.

Aspect 3: The transceiver of Aspect 1 or 2, further comprising a switch coupled between a voltage rail and a tap of the primary winding.

Aspect 4: The transceiver according to any of Aspects 1-3, further comprising a switch coupled between the first terminal of the secondary winding and the reference potential node.

Aspect 5: The transceiver according to any of Aspects 1-4, further comprising a second inductive element coupled between the first terminal of the secondary winding and the input of the second amplifier.

Aspect 6: The transceiver according to any of Aspects 1-5, wherein the first output of the first amplifier is coupled to a first terminal of the primary winding, and wherein the first amplifier comprises a second output coupled to a second terminal of the primary winding.

Aspect 7: The transceiver according to any of Aspects 1-6, wherein the first amplifier comprises: an input transistor including a gate coupled to an input node of the transceiver; and a cascode transistor coupled in cascode between the input transistor and the primary winding.

Aspect 8: The transceiver of Aspect 7, wherein the input transistor and the cascode transistor are configured to be turned on in saturation during a receive mode of the transceiver.

Aspect 9: The transceiver of Aspect 7 or 8, wherein the input transistor and the cascode transistor are n-type field-effect transistors (NFETs) and wherein gates of the input transistor and the cascode transistor are configured to be coupled to a voltage rail of the transceiver during a receive mode of the transceiver.

Aspect 10: The transceiver according to any of Aspects 1-9, further comprising: a first switch coupled between a voltage rail and a tap of the primary winding and configured to be closed during a transmit mode of the transceiver and to be open during a receive mode of the transceiver; and a second switch coupled between the first terminal of the secondary winding and the reference potential node and configured to be closed during the transmit mode of the transceiver and to be open during the receive mode of the transceiver.

Aspect 11: The transceiver according to any of Aspects 1-10, wherein the first amplifier is configured to electrically short a first terminal and a second terminal of the primary winding to the reference potential node during a receive mode of the transceiver.

Aspect 12: The transceiver according to any of Aspects 1-11, wherein the first amplifier comprises a power amplifier (PA), and wherein the second amplifier comprises a low-noise amplifier (LNA).

Aspect 13: A method for wireless communication, comprising: electrically shorting, via a first amplifier, a primary winding of a transformer to a reference potential node during a receive mode, wherein a first terminal of a secondary winding of the transformer is coupled to an input of a second amplifier, and wherein a second terminal of the secondary winding is coupled to an antenna; and amplifying, via the second amplifier, a signal received from the antenna through the secondary winding of the transformer.

Aspect 14: The method of Aspect 13, wherein a first inductive element is coupled between the first terminal of the secondary winding and the reference potential node.

Aspect 15: The method of Aspect 14, wherein a capacitive element is coupled in series with the first inductive element between the first terminal of the secondary winding and the reference potential node.

Aspect 16: The method according to any of Aspects 13-15, further comprising: coupling a voltage rail to a tap of the primary winding during a transmit mode; and amplifying, via the first amplifier, a signal to be provided to the primary winding of the transformer for transmission during the transmit mode.

Aspect 17: The method according to any of Aspects 13-16, further comprising coupling the first terminal of the secondary winding to the reference potential node during a transmit mode.

Aspect 18: The method according to any of Aspects 13-17, wherein electrically shorting the primary winding of the transformer to the reference potential node comprises turning on in saturation a transistor of the first amplifier coupled between the primary winding and the reference potential node.

Aspect 19: The method according to any of Aspects 13-18, wherein: the first amplifier comprises an input transistor including a gate coupled to an input node and a cascode transistor coupled in cascode between the input transistor and the primary winding; the input transistor and the cascode transistor are n-type field-effect transistors (NFETs); and electrically shorting the primary winding of the transformer to the reference potential node comprises providing a supply voltage to gates of the input transistor and the cascode transistor.

Aspect 20: A wireless device, comprising: an antenna; a transformer having a primary winding and a secondary winding; a first amplifier having an output coupled to the primary winding; a second amplifier having an input coupled to a first terminal of the secondary winding, wherein a second terminal of the secondary winding is coupled to the antenna; and an inductive element coupled between the second terminal of the secondary winding and a reference potential node.

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. A transceiver, comprising:
a transformer having a primary winding and a secondary winding;
a first amplifier having a first output coupled to the primary winding;
a second amplifier having an input coupled to a first terminal of the secondary winding, wherein a second terminal of the secondary winding is coupled to an antenna port of the transceiver; and
a first inductive element coupled between the first terminal of the secondary winding and a reference potential node.

2. The transceiver of claim 1, further comprising a capacitive element coupled in series with the first inductive element between the first terminal of the secondary winding and the reference potential node.

3. The transceiver of claim 1, further comprising a switch coupled between a voltage rail and a tap of the primary winding.

4. The transceiver of claim 1, further comprising a switch coupled between the first terminal of the secondary winding and the reference potential node.

5. The transceiver of claim 1, further comprising a second inductive element coupled between the first terminal of the secondary winding and the input of the second amplifier.

6. The transceiver of claim 1, wherein the first output of the first amplifier is coupled to a first terminal of the primary winding, and wherein the first amplifier comprises a second output coupled to a second terminal of the primary winding.

7. The transceiver of claim 1, wherein the first amplifier comprises:
an input transistor including a gate coupled to an input node of the transceiver; and
a cascode transistor coupled in cascode between the input transistor and the primary winding.

8. The transceiver of claim 7, wherein the input transistor and the cascode transistor are configured to be turned on in saturation during a receive mode of the transceiver.

9. The transceiver of claim 7, wherein the input transistor and the cascode transistor are n-type field-effect transistors (NFETs) and wherein gates of the input transistor and the cascode transistor are configured to be coupled to a voltage rail of the transceiver during a receive mode of the transceiver.

10. The transceiver of claim 1, further comprising:
a first switch coupled between a voltage rail and a tap of the primary winding and configured to be closed during a transmit mode of the transceiver and to be open during a receive mode of the transceiver; and
a second switch coupled between the first terminal of the secondary winding and the reference potential node and configured to be closed during the transmit mode of the transceiver and to be open during the receive mode of the transceiver.

11. The transceiver of claim 1, wherein the first amplifier is configured to electrically short a first terminal and a second terminal of the primary winding to the reference potential node during a receive mode of the transceiver.

12. The transceiver of claim 1, wherein the first amplifier comprises a power amplifier (PA), and wherein the second amplifier comprises a low-noise amplifier (LNA).

13. A method for wireless communication, comprising:
electrically shorting, via a first amplifier, a primary winding of a transformer to a reference potential node during a receive mode, wherein a first terminal of a secondary winding of the transformer is coupled to an input of a second amplifier, and wherein a second terminal of the secondary winding is coupled to an antenna; and
amplifying, via the second amplifier, a signal received from the antenna through the secondary winding of the transformer.

14. The method of claim 13, wherein a first inductive element is coupled between the first terminal of the secondary winding and the reference potential node.

15. The method of claim 14, wherein a capacitive element is coupled in series with the first inductive element between the first terminal of the secondary winding and the reference potential node.

16. The method of claim 13, further comprising:
coupling a voltage rail to a tap of the primary winding during a transmit mode; and
amplifying, via the first amplifier, a signal to be provided to the primary winding of the transformer for transmission during the transmit mode.

17. The method of claim 13, further comprising coupling the first terminal of the secondary winding to the reference potential node during a transmit mode.

18. The method of claim 13, wherein electrically shorting the primary winding of the transformer to the reference potential node comprises turning on in saturation a transistor of the first amplifier coupled between the primary winding and the reference potential node.

19. The method of claim 13, wherein:
the first amplifier comprises an input transistor including a gate coupled to an input node and a cascode transistor coupled in cascode between the input transistor and the primary winding;
the input transistor and the cascode transistor are n-type field-effect transistors (NFETs); and
electrically shorting the primary winding of the transformer to the reference potential node comprises providing a supply voltage to gates of the input transistor and the cascode transistor.

20. A wireless device, comprising:
an antenna;
a transformer having a primary winding and a secondary winding;
a first amplifier having an output coupled to the primary winding;
a second amplifier having an input coupled to a first terminal of the secondary winding, wherein a second terminal of the secondary winding is coupled to the antenna; and
an inductive element coupled between the second terminal of the secondary winding and a reference potential node.
